(19) United States
(12) Patent Application Publication
(10) Pub. No.: US 2006/0175681 A1
(43) Pub. Date: Aug. 10, 2006

(54) Method to grow III-nitride materials using no buffer layer

(76) Inventor: Jing Li, Manhattan, KS (US)

Correspondence Address: SHOOK, HARDY & BACON LLP;INTELLECTUAL PROPERTY DEPARTMENT, 2555 GRAND BLVD, KANSAS CITY,, MO, 64108-2613, US

(21) Appl. No.: 11/103,846

(22) Filed: Apr. 12, 2005

Related U.S. Application Data
(60) Provisional application No. 60/650,929, filed on Feb. 8, 2005.

(51) Int. Cl. H01L 29/12

(52) U.S. Cl. 257/613

(57) ABSTRACT

Disclosed is a method for growing nitride compound semiconductors on sapphire substrates where no low-temperature buffer layer is used. The nitride based compound semiconductor materials and devices grown by the method of the present invention have crystallinity and surface morphology at practical levels with high quality, high stability, and high yield.

### CROSS-REFERENCE TO RELATED APPLICATIONS

This application claims the benefit of U.S. Provisional Application No. 60/650,929 filed Feb. 8, 2005 under the same title.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the Contract No. DMI-0450314 awarded by the National Science Foundation.

### BACKGROUND OF THE INVENTION

1. Field of the Invention

The present invention relates to the field of growing III-nitride-based compound semiconductor materials and devices epitaxially on substrates (e.g., sapphire) and particularly, to a method of growing high-quality III-nitride-based compound semiconductor materials and devices without using a buffer layer.

2. Description of the Related Art

The III-nitride semiconductors have recently been the focus of intense research activity due to the rapid development of gallium nitride (GaN)-based optoelectronic and electronic devices. When alloyed with InN and AlN, GaN offers a range of optical emission from infrared to the ultraviolet (UV) spectral region. Especially the III-nitride binary (GaN, AlN, and InN) and III-nitride ternary (AlGaN, InGaN, and InAlN) and quaternary (InAlGaN) alloys have demonstrated great promise for applications in optoelectronic devices, particularly for green/blue/UV/white light emitting diodes (LEDs) and blue/UV laser diodes (LDs). Nitride materials include the binary materials (GaN, AlN, and InN) and ternary (AlGaN, InGaN, and InAlN) and quaternary (InAlGaN) alloys.

Nitride materials are also emerging as promising materials for next generation high-temperature and high-power microelectronic devices due to their large band gap and chemical and thermal stability. For example, heterojunction field effect transistors (HFETs) based on AlGaN/GaN heterostructures have performed well. Other applications of III-nitride semiconductors include solar blind or visible blind UV detectors.

Due to the lack of the bulk III-nitride crystals, nitride materials are commonly epitaxially grown on foreign substrates, including sapphire (Al₂O₃), SiC, and Si.

When nitride materials are directly grown on foreign substrates, the growth mode is three-dimensional due to the large lattice mismatch, chemical dissimilarity and thermal expansion coefficient difference between the nitride materials and substrate. Conventionally, in order to improve the quality of the grown layers, a thin layer of AlN or GaN or nitride material is deposited at a lower temperature prior to the growth of expitaxial nitride materials at higher temperatures. This low temperature layer serves as a buffer layer (hereafter as low T buffer layer) and provides nucleation sites for epitaxial growth of the subsequent nitride materials.

Various techniques for the growth of nitride materials have been employed to obtain high quality nitride materials. An AlN low temperature buffer layer has been described by Isamu Akasaki and Nobuhiko Sawaki (U.S. Pat. No. 4,855,249), Katsuhide Manabe et al. (U.S. Pat. No. 5,122,845), H. Amano et al., “Metalorganic vapor phase epitaxial growth of a high quality GaN film using an AlN buffer layer,” Applied Physics Letter, Vol. 48, May 1986, Page 353. In this method, before the growth of an epitaxial layer of a nitride material, an AlN low T buffer layer with a thickness of 10 to 50 nm is formed on a sapphire substrate at a relatively low growth temperature of 400° C. to 900° C. to serve as a nucleation layer. According to this method, the crystallinity and the surface morphology of nitride epitaxial layers and devices can be improved.

Shuji Nakamura (U.S. Pat. No. 4,855,249), proposed a method of using a GaN layer grown at a low temperature to serve as a buffer layer. The crystallinity, surface morphology, electric and optical properties of the nitride materials and devices grown on top of the low T buffer layer can be drastically improved.

A low T buffer layer is necessary to grow high quality nitride materials and enables p-type doping. In these methods, however, it is necessary to strictly restrict the growth conditions of the low T buffer layer. For example, the thickness of the buffer layer has to be controlled in a very small range (10 to 50 nm) in order to get high quality epilayer. The growth temperature must also be controlled to be lower than the growth temperature of the subsequent nitride epitaxial layers so that the buffer layer does not become mono-crystalline.

Because the low T buffer layer requires growth conditions which are very different than the subsequent nitride materials, extra time and effort are required. This time and effort must be expended to change the growth conditions between the low T buffer layer and the subsequent nitride epilayers and device structures. Moreover, the growth conditions and buffer-layer thicknesses may vary for nitride materials with different compositions. These added demands create even more delays and require further efforts to optimize the growth conditions of buffer layers and the subsequent nitride materials.

### SUMMARY OF THE INVENTION

The present invention provides a method for the growth of nitride materials and devices on sapphire substrate with no buffer layers with high crystalline quality, good surface morphology, high stability, high yield, and good performance. The method includes treating a substrate, e.g., sapphire with a metal. In the preferred embodiment, said metal comprises one of Aluminum, Gallium, Indium, Silicon, and Zirconium from a metalorganic source. Next, high quality nitride materials and devices are grown on the sapphire substrate. Aluminum has been used in the disclosed embodiments. The process avoids the deposition of a buffer layer.

### BRIEF DESCRIPTION OF THE DRAWINGS

FIG. 1 is a schematic diagram of nitride material or device using a conventional crystal growth method (using a low T buffer layer).

FIG. 2 is a schematic diagram of nitride material or device using the crystal growth method of the present invention (with no low T buffer layer).

FIG. 3 is the optical microscopy image showing the surface morphology of a GaN epilayer wafer grown by the method of the present invention.

FIG. 4 is a chart comparing the x-ray diffraction (XRD) rocking curves of the AlGaN epilayers grown by the method of the present invention (with no low T buffer) and the method of the prior art (including a low T buffer layer).

### DETAILED DESCRIPTION OF THE INVENTION

The present invention has numerous advantages over the prior art methods. The first of these is simplicity. This is because no low T buffer layer is needed for the subsequent growth of the high quality nitride materials. This affords more choices and higher flexibility in growing many different material structures and devices. The second is lower cost. Less time is required for nitride material growth. Thus, materials such as H2, NH3, and metal organic sources are conserved, and less manpower is required. Also, the yield will be higher. The third is higher quality. Though the conventional growth of a low T buffer layer can improve the quality of the subsequent nitride epilayer, it is a low quality layer itself (e.g., most often it is amorphous). Thus, the buffer layer may absorb light in the UV/blue/green wavelength and introduce defects.

The crystal growth method for high quality nitride materials and devices of the present invention comprises treating the substrate (e.g., sapphire) using one of Aluminum, Gallium, Indium, Silicon, and Zirconium. Aluminum is preferred. The Aluminum is introduced to the substrate using Trimethylaluminum (TMAl) gas flow or some other deposition means. Subsequently nitride materials are grown directly onto the substrate. It is also possible that some other material could be grown upon the Aluminum treated surface of the substrate, and then the nitrides grown on top of it. No buffer layer is formed. Rather, the Aluminum is used to metalize the substrate surface so that it is Aluminum terminated. This enables the device to be manufactured without a buffer layer.

The aluminum treatment is accomplished by flowing the metal organic (MO) source gas such as Trimethylaluminum (TMAl) into the reactor of a metal organic chemical vapor deposition system, which contains the substrate. Subsequently the surface of the substrate is modified. It is expected that the metal treatment affects the first few atomic layers (or a few angstroms) of the substrate surface.

The extent of the metal treatment should result in the sapphire (Al₂O₃) substrate face being substantially terminated with Al.

The temperature for Al treatment is the same as the growth temperature for the subsequent nitride materials. Thus, unlike the prior art methods, the same temperature is maintained throughout the Al-treatment and nitride-growth steps. The Al treatment time is adjusted to between 1 to 60 seconds depending on the TMAl gas flow rate.

Al treatment alters the surface state of the substrate such that the subsequent growth of the nitride epilayer will favor the substrate according to the II-face (instead of V face) growth (notice the materials of interest are III-V semiconductors) and hence improve the quality of the subsequently grown epilayers.

This overcomes the need for a buffer layer which was required with the prior art devices. With these earlier devices, the low temperature AlN or GaN buffer was grown to ensure that the atoms of the subsequent layer will not move easily to ensure two dimensional growth as desired.

Here, the Al treatment termination accomplishes the desired two-dimensional growth characteristics without using a buffer layer.

The epitaxial layers of the nitride materials on the Al treated substrate are represented by formula AlₓIn_{y}Ga_{1-x-y}N to include nitride compound GaN, InN, AlN and alloys, where x and/or y may vary from 0 to 1.

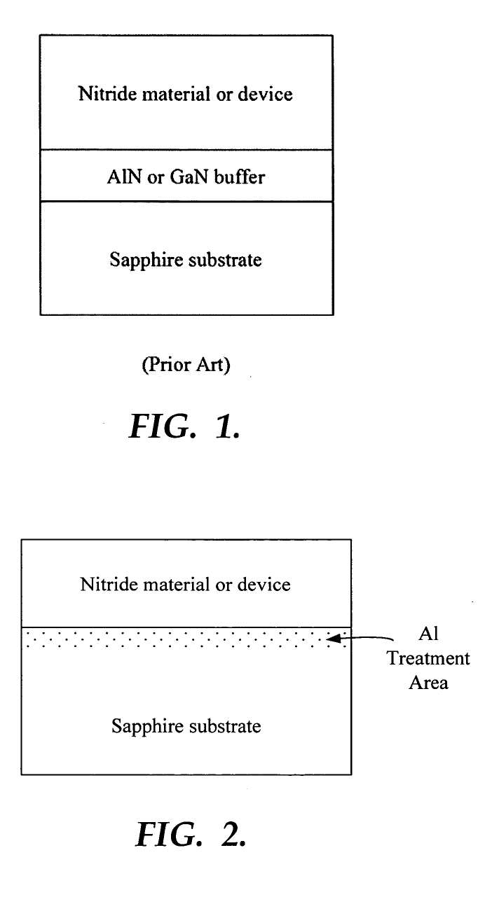

FIG. 1 is the schematic diagram of an epitaxial wafer grown by the method of the prior art.

FIG. 2 shows the schematic diagram of an epitaxial wafer grown by the method of the present invention.

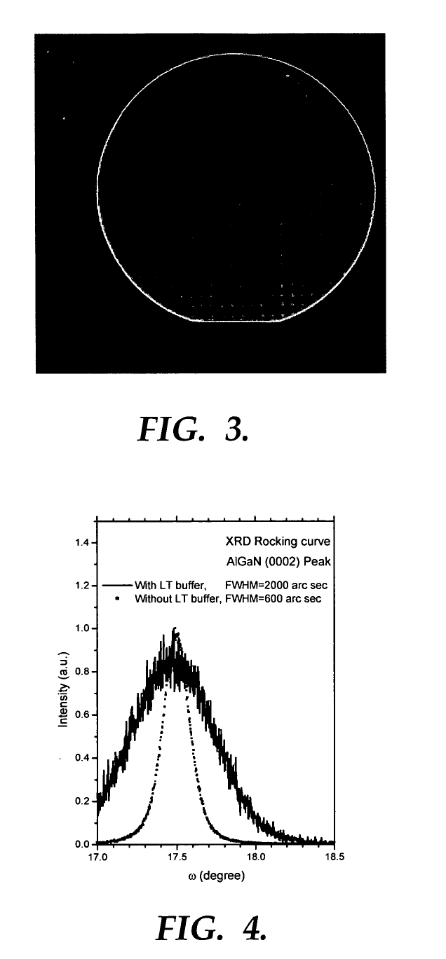

FIG. 3 shows the optical microscopy image of a nitride material grown on sapphire by the method of the present invention (with no low T buffer layer), showing the surface morphology. The surface is mirror-like and uniform. There is also no cracking visible on the wafer.

FIG. 4 compares the XRD rocking curves of two AlGaN epilayer samples grown using the method of the present invention (with no buffer layer) and the conventional method of the prior art (with a low temperature buffer layer). The two samples were grown in the same metal-organic chemical deposition system. The full width at half maximum (FWHM) of XRD rocking curve of the AlGaN epilayer grown using the conventional method with a low temperature buffer is much broader (˜2000 arcsec) than the one grown using the method of the present invention (˜600 arcsec).

These results demonstrate that the low T buffer layer is not necessary for the growth of high quality nitride epilayers and devices on sapphire substrates. The advantageous features of the method of the present invention for the growth of nitride materials and devices with no buffer layer are thus clearly demonstrated.

In summary, the invention comprises a crystal growth method for a the group III nitride-based compound semiconductor. This process includes an Al treatment step.

In one embodiment, the Al treatment temperature is from about 500 to 1400° C. and the substrate is treated with Aluminum using a reaction gas containing at least one gas selected from the group consisting TMAl and TEAl. The process may further include the step of growing an AlₓIn_{y}Ga_{1-x-y}N, where x and/or y could vary from 0 to 1.

Because of the Aluminum treatment, Nitride epilayers, including GaN, InN and AlN may be directly grown on the sapphire substrate. The Aluminum treatment, however, also enables the growth of other materials without using a buffer layer. For example, Nitride alloys, including InGaN, AlGaN, InAlN and InAlGaN may also be grown on the sapphire substrate without using a buffer layer. Similarly, quantum wells, including but not limited to InGaN/InGaN, InGaN/AlGaN, InGaN/InAlN, AlGaN/AlGaN, AlGaN/InGaN, InGaN/InAlGaN, AlGaN/InAlGaN, InAlN/InAlGaN, InGaN/InGaN, are also able to be grown on the sapphire substrate without using a buffer layer. Likewise, Nitride heterostructures, including but not limited to InGaN/InGaN, InGaN/AlGaN, InGaN/InAlN, AlGaN/AlGaN, AlGaN/InGaN, InGaN/InAlGaN, AlGaN/InAlGaN, InAlN/InAlGaN, InGaN/InGaN, are also able to be grown according to the methods of the present invention. Further, Nitride based HFET devices may be grown on the substrate without using a low-temperature buffer layer. Also possible is that blue/green/UV LEDs based on nitride materials can be are directly grown on the substrate without the use of a buffer layer. Detectors based on nitride materials directly grown on the sapphire substrate.

Though numerous examples of materials and devices are specified above as being capable of being grown without low-temperature buffer layers according to the methods of the present invention, it should be noted that other nitride materials and structures could be grown as well and still fall within the scope of the present invention.

It is possible that all of the above-noted materials and devices, because of the Aluminum treatment, can be grown directly on the substrate. It should be noted, however, that an intermediate material can be grown on the Aluminum-treated surface, and then the nitride materials grown after that.

Following are three examples illustrative of the present invention. It should be understood that these are presented as examples only, and should not be considered as limiting the scope of this invention which would include numerous embodiments not shown.

### EXAMPLE 1

An AlGaN epitaxial layer was grown to have a film thickness of 2 μm on a sapphire substrate in accordance with the present invention with the following steps.

First, A sapphire substrate having a diameter of 2 inches was placed on a susceptor.

Next, the air in reactor was sufficiently exhausted by an exhaust pump, and H₂ gas was introduced into the reactor, thus replacing the air in the reactor with H₂ gas.

Thereafter, the susceptor was heated up to 1100° C. by a heater while supplying H₂ gas into the reactor. This state was held for around 10 minutes to remove contaminations from the surface of the sapphire substrate.

Subsequently, while maintaining the susceptor at 1100° C., a gas mixture of H₂ and TMAl supplied from a metal-organic (MO) source is injected into the reactor for 10 seconds to treat the substrate surface with Aluminum. This results in a modification in the surface state of the sapphire (Al₂O₃) substrate. The substrate should be substantially terminated with an Aluminum face. The flow rate of H₂ in MO source injection is 10 l/min, and the flow rate of TMAl is 100 ml/min.

Then a gas mixture of ammonia gas and H₂ gas was supplied from the reaction gas NH₃ injection. The flow rate of H₂ in NH₃ injection is 5 l/min, and the flow rate of NH₃ is 300 ml/min. This state was maintained until about 1 μm of AlN was grown.

Thereafter, Trimethylgallium (TMGa) gas was introduced from the MO gas injection. The flow rate of TMGa ramped from is 5 ml/min to 50 ml/min. At the same time, the flow rate of TMAl gas reduced from 100 mil/min to 60 ml/min, and the flow rate of NH₃ increased from 300 ml/min to 3000 ml/min, to grow an AlGaN grading layer with variable Al content. The total time for this layer is about 1000 seconds resulting a 0.4 μm AlGaN grading layer.

After the grading layer, TMGa gas was flown at a flow rate of 50 ml/min, and TMAl gas was flown at a flow rate of 60 ml/min, and the NH₃ gas was flown at a flow rate of 3000 ml/min. In this layer, silane (200 ppm diluted in H₂) was introduced to form an n type AlGaN. The flow rate silane is 1.5 ml/min. The growth of this layer lasted for about 60 minutes, thereby growing an AlGaN epitaxial layer to have a film thickness of 1.5 μm.

After the growth, a Hall measurement was performed at room temperature to obtain the carrier concentration and the mobility of the AlGaN epitaxial layer. XRD measurement was performed to obtain the Al content.

### EXAMPLE 2

An n-GaN was grown on a sapphire substrate in accordance with the present invention with the following steps.

A sapphire substrate having a diameter of 2 inches was placed on a susceptor.

Next, the air in reactor was sufficiently exhausted by an exhaust pump, and H₂ gas was introduced into the reactor, thus replacing the air in the reactor with H₂ gas.

Thereafter, the susceptor was heated up to 1100° C. by a heater while supplying H₂ gas into the reactor. This state was held for 10 minutes to remove contaminations from the surface of the sapphire substrate. The temperature of the susceptor was maintained at 1100° C.

Subsequently, a gas mixture of H₂ and TMAl gas supplied from the MO injection to the reactor for about 2-30 seconds in order that the surface of the substrate is treated with Aluminum. This results in a modification in the surface state of the sapphire (Al₂O₃) substrate (or results in the substrate being substantially terminated with an Al face).

The flow rate of H₂ in MO injection is 10 l/min, and the flow rate of TMAl gas is 100 ml/min.

Then a gas mixture of ammonia (NH₃) gas and H₂ gas was supplied from the reaction gas NH₃ injection. The flow rate of H₂ in NH₃ injection is 5 l/min, and the flow rate of NH₃ is 5000 ml/min. A gas mixture of H₂ and TMGa supplied from the MO injection to the reactor for GaN growth. The flow rate of TMGa is 50 ml/min.

Thereafter, SiH₄ gas was introduced from the MO gas injection to grow n-type GaN.

After the growth, a Hall measurement was performed at room temperature to obtain the carrier concentration and the mobility of the GaN epitaxial layer.

### EXAMPLE 3

An InGaN/GaN multiple quantum well (MQW) LED structure was grown on a sapphire substrate in accordance with the present invention with the following steps.

A sapphire substrate having a diameter of 2 inches was placed on a susceptor.

Next, the air in reactor was sufficiently exhausted by an exhaust pump, and H₂ gas was introduced into the reactor, thus replacing the air in the reactor with H₂ gas.

Thereafter, the susceptor was heated up to 1100° C. by a heater while supplying H₂ gas into the reactor. This state was held for 10 minutes to remove contaminations from the surface of the sapphire substrate. The temperature of the susceptor was maintained at 1100° C.

Subsequently, a gas mixture of H₂ and TMAl gas was supplied via MO injection to the reactor for about 2-30 seconds to treat the substrate surface with Al. This resulted in a modification in the surface state of the sapphire (Al₂O₃) substrate. Thus, the substrate was substantially terminated on its face with Al. The flow rate of H₂ in MO injection was 10 l/min, and the flow rate of TMAl gas was 100 ml/min.

Then a gas mixture of ammonia (NH₃) gas and H₂ gas was supplied from the reaction gas NH₃ injection. The flow rate of H₂ in NH₃ injection was 5 l/min, and the flow rate of NH₃ was 5000 ml/min. A gas mixture of H₂ and TMGa was supplied from the MO injection to the reactor for GaN growth. The flow rate of TMGa was 50 ml/min, and the thickness for the undoped GaN layer was about 1 μm.

Thereafter, SiH₄ gas was introduced from the MO gas injection to grow about 2 μm thick n-type GaN.

Then, the susceptor temperature was decreased to about 780° C. to grow an InGaN/GaN MQW by flowing TMIn, TMGa and NH₃ to the reactor.

After the MQW growth, the susceptor temperature was increase to about 1000° C. to grow a 0.2 μm Mg doped p-GaN.

After the p-type GaN growth, the temperature was decreased to about 750° C., and only N₂ was flowed over the wafer to anneal the wafer for 10 minutes.

The resulting LED wafer had very bright blue light emission at 20 mA current injection.

Again, none of the three examples disclosed should be considered limiting with respect to the scope of the present invention. Even though each of these examples disclose embodiments in which the nitride materials are grown directly on the metal-treated substrate with no buffer being used, it is very possible that a buffer could be grown on the treated surfaces and then the nitride materials grown above the buffer. It is very possible that adding a low T buffer layer intermediate the Al-treated surface and the nitrides might even further improve performance. Thus, the scope of the present invention should not be limited to embodiments in which the nitrides are grown directly on the treated surface.

The figures attached hereto are illustrative of the articles created.

FIG. 1 is a schematic diagram of nitride material structure or device using the conventional growth method of the prior art. With the prior art methods, an AlN or GaN buffer layer is grown on the substrate before the deposition of the Nitride material. This is done at a lower temperature than the growth temperature of the subsequent nitride material or device.

FIG. 2 is a schematic diagram of a nitride material structure or device which uses the growth methods of the present invention. In its processing, the temperature for Al treatment is the same as the growth temperature for the subsequent nitride material or device. The Al treatment time is adjusted to between 1 to 60 seconds depending on the TMAl gas flow rate.

There is no layer required. Instead, the substrate is treated with the aluminum.

FIG. 3 shows the created article under microscope. The figures shows an optical microscopy image of a GaN epiwafer (2-inch in diameter) grown on sapphire by the method of the present invention. From the photograph, the smooth surface morphology of the GaN epilayer may be seen which makes accomplishing the objectives of the possible.

FIG. 4 shows XRD rocking curves for two AlGaN epilayer samples grown using (1) the method of the present invention (with no buffer layer, dotted line) versus (2) the conventional method of the prior art (with a low temperature buffer layer, solid line). Two samples were grown in the same metal organic chemical deposition system. The full width at half maximum (FWHM) of XRD rocking curve of an AlGaN epilayer grown using the conventional method with a low temperature buffer is much broader (˜2000 arcsec) than the one grown using the method of the present invention (˜600 arcsec).

As can be seen, the present invention and its equivalents are well-adapted to provide a new and useful semi-conductor device and associated method of creating such a device using growing III-nitride-based compound semiconductor materials without the necessity of a buffer layer. Many different arrangements of the various components depicted, as well as components not shown, are possible without departing from the spirit and scope of the present invention.

The present invention has been described in relation to particular embodiments, which are intended in all respects to be illustrative rather than restrictive. Alternative embodiments will become apparent to those skilled in the art that do not depart from its scope. Many alternative embodiments exist but are not included because of the nature of this invention. A skilled artisan may develop alternative means of implementing the aforementioned improvements without departing from the scope of the present invention.

It will be understood that certain features and subcombinations are of utility and may be employed without reference to other features and subcombinations and are contemplated within the scope of the claims. Not all steps listed in the various figures need be carried out order described.

The invention claimed is:

1. A process of creating a semiconductor device by growing nitride materials on a substrate, said method comprising:
treating a surface of said substrate with a metal; and
growing said nitride materials.

2. The process of claim 1 wherein said treating step comprises:
selecting one of Aluminum, Gallium, Indium, Silicon, and Zirconium as said metal.

3. The process of claim 1 comprising:
selecting Aluminum as the metal used in said treating step.

4. The process of claim 3 comprising:
deriving said Aluminum from a metalorganic source.

5. The process of claim 4 comprising:
providing Trimethylaluminum gas to serve as said metalorganic source.

6. The process of claim 1 including:
comprising said substrate of sapphire.

7. The process of claim 1 comprising:
maintaining substantially the same temperature during at least some of said treating step and at least some of said growing step.

8. The process of claim 1 comprising:
using said treating step to eliminate the need for a buffer layer; and
growing said nitride materials directly on said treated surface.

9. The process of claim 1 wherein said growing step occurs directly on said substrate.

10. A semiconductor device comprising:
a substrate;
a surface on said substrate, said surface being treated with a metal; and
nitride materials grown above said treated substrate.

11. The device of claim 10 wherein said metal is one of Aluminum, Gallium, Indium, Silicon, and Zirconium.

12. The device of claim 10 wherein said metal is Aluminum.

13. The device of claim 12 wherein said Aluminum is derived from a metalorganic source.

14. The device of claim 13 wherein said metalorganic source is Trimethylaluminum gas.

15. The device of claim 10 wherein said substrate comprises sapphire.

16. The device of claim 10 wherein said metal enables said treated surface to be formed at substantially the same temperature at which the nitrides are grown on said substrate.

17. The device of claim 11 wherein said nitride materials are grown directly on said substrate.

18. A method of creating a semiconductor device comprising:
providing a substrate;
treating a surface of said substrate with one of Aluminum, Gallium, Indium, Silicon, and Zirconium; and
growing one of GaN, InN, AlN, Nitride alloys, InGaN, AlGaN, InAlN, InAlGaN, quantum wells, InGaN/InGaN, InGaN/AlGaN, InGaN/InAlN, AlGaN/AlGaN, AlGaN/InGaN, InGaN/InAlGaN, AlGaN/InAlGaN, InAlN/InAlGaN, InGaN/InGaN, Nitride heterostructures, Nitride-based HFET devices, blue/green/UV LEDs, and detectors based on nitride materials above said treated substrate.

19. The process of claim 18 comprising:
maintaining substantially the same temperature during said treating step and said growing step.

20. The process of claim 18 comprising:
using said treatment step to enable said growing to occur directly on said treated surface.
